(19) United States
(12) Patent Application Publication
(10) Pub. No.: US 2015/0270240 A1
(43) Pub. Date: Sep. 24, 2015

(54) POWER SEMICONDUCTOR DEVICE

(71) Applicant: Mitsubishi Electric Corporation, Tokyo (JP)

(72) Inventor: Koichi TOKUBO, Tokyo (JP)

(73) Assignee: Mitsubishi Electric Corporation, Tokyo (JP)

(21) Appl. No.: 14/572,650

(22) Filed: Dec. 16, 2014

(30) Foreign Application Priority Data
Mar. 20, 2014 (JP) 2014-058200

(51) Int. Cl. H01L 23/00

(52) U.S. Cl. CPC H01L 24/49; H01L 2924/10272; H01L 2924/10329; H01L 2224/49051; H01L 2224/49095; H01L 2224/48091; H01L 2224/48106; H01L 2224/48227; H01L 2224/4903

(57) ABSTRACT

A power semiconductor element includes an electrode layer made of a conductor. A first wiring portion is made of a conductor and is apart from the power semiconductor element. At least one main bonding wire has one end on the electrode layer and the other end on the first wiring portion. At least one sub-bonding wire supports the main bonding wire and has both ends on one of the electrode layer and the first wiring portion.

### BACKGROUND OF THE INVENTION

1. Field of the Invention

The present invention relates to a power semiconductor device and more particularly to a power semiconductor device including a bonding wire.

2. Description of the Background Art

Bonding wires are often used to carry out wiring inside semiconductor modules. The bonding wire is made of a metal such as copper, silver, or gold and has a wire diameter of, for example, about 100 to 500 μm.

The wire loop height of the bonding wire that has been wired may affect the height dimension of the semiconductor device. Thus, in many cases, the wire loop height is desired to be low in terms of size of the semiconductor device. Meanwhile, if a wire loop having a low height is used, there is a concern over undesirably excessive approach to or contact with the peripheral positions having different potentials. Therefore, methods for coping with the above concern have been under review.

According to Japanese Patent Application Laid-Open No. 2003-31605, when the wire bonding is performed on the semiconductor chip to manufacture the semiconductor module, in order to avoid contact between the wire loop and the component near the loop and ensure the desirable wire loop height, a different wire loop (also referred to as tie wire) that shores up the wire loop is formed in advance. This can avoid contact between the wire loop and the component near the loop and ensure the desirable wire loop height.

In the technique described in Japanese Patent Application Laid-Open No. 2003-31605, the mechanical stability of the bonding wire can be enhanced by the tie wire. However, the performance required of the bonding wire is not limited to the mechanical stability.

Particularly, in a case where the semiconductor device is a power semiconductor device (power module), a large current flows through the bonding wire that carries a current (main current) controlled by the power semiconductor device. In such a case where a large current is handled, the local concentration of current can be a problem. Therefore, in many cases, the power module includes, for the main current, not one bonding wire but a plurality of bonding wires that are disposed in parallel. For example, in many cases, not one but several bonding wires are bonded to the source electrode pad of the power metal oxide semiconductor field effect transistor (MOSFET). However, there are limits to the number and the arrangement of the bonding wires disposed in parallel as described above. Therefore, a method that can replace or can be combined with the above method is required.

### SUMMARY OF THE INVENTION

The present invention therefore has been made to solve the problem described above, and an object thereof is to provide a power semiconductor device in which the concentration of current can be relieved by dispersing an electrical path between an electrode layer of a power semiconductor element and a wiring portion while the mechanical stability of the electrical path is enhanced.

A power semiconductor device according to the present invention includes a power semiconductor element, a first wiring portion, at least one main bonding wire, and at least one sub-bonding wire. The power semiconductor element includes an electrode layer made of a conductor. The first wiring portion is made of a conductor and is apart from the power semiconductor element. The at least one main bonding wire has one end on the electrode layer and the other end on the first wiring portion. The at least one sub-bonding wire supports the main bonding wire and has both ends on one of the electrode layer and the first wiring portion.

In the power semiconductor device according to the present invention, the main bonding wire that electrically connects the electrode layer of the power semiconductor element and the wiring portion is supported by the sub-bonding wire. This can enhance the mechanical stability of the electrical path between the electrode layer of the power semiconductor element and the wiring portion. Therefore, the undesirable approach of the main bonding wire as the electrical path between the power semiconductor element and the wiring portion to the peripheral position having a different potential can be prevented.

The electrical path between the electrode layer of the power semiconductor device and the wiring portion is formed not only by the main bonding wire but also by the sub-bonding wire. Consequently, the electrical path is dispersed. The concentration of current in this power semiconductor device can be thus relieved.

Therefore, the concentration of current can be relieved by dispersing the electrical path between the electrode layer of the power semiconductor element and the wiring portion while the mechanical stability of the electrical path is enhanced.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is a partial plan view schematically showing a configuration of a power semiconductor device according to a first preferred embodiment of the present invention and FIG. 1B is a schematic partial cross-sectional view taken along the line IB-IB in FIG. 1A;

FIG. 2A is a partial plan view schematically showing a configuration of a power semiconductor device according to a second preferred embodiment of the present invention and FIG. 2B is a schematic partial cross-sectional view taken along the line IIB-IIB in FIG. 2A;

FIG. 3A is a partial plan view schematically showing a configuration of a power semiconductor device according to a third preferred embodiment of the present invention and FIG. 3B is a schematic partial cross-sectional view taken along the line IIIB-IIIB in FIG. 3A;

FIG. 4A is a partial plan view schematically showing a configuration of a power semiconductor device according to a fourth preferred embodiment of the present invention and FIG. 4B is a schematic partial cross-sectional view taken along the line IVB-IVB in FIG. 4A; and

FIG. 5A is a partial plan view schematically showing a configuration of a power semiconductor device according to a fifth preferred embodiment of the present invention, FIG. 5B is a schematic partial cross-sectional view taken along the line VB-VB in FIG. 5A, and FIG. 5C is a schematic partial cross-sectional view taken along the line VC-VC in FIG. 5A.

### DESCRIPTION OF THE PREFERRED EMBODIMENTS

Preferred embodiments of the present invention are described below with reference to the drawings. In the drawings below, the same or corresponding portions are given the same reference signs and the description thereof is not repeated.

### First Preferred Embodiment

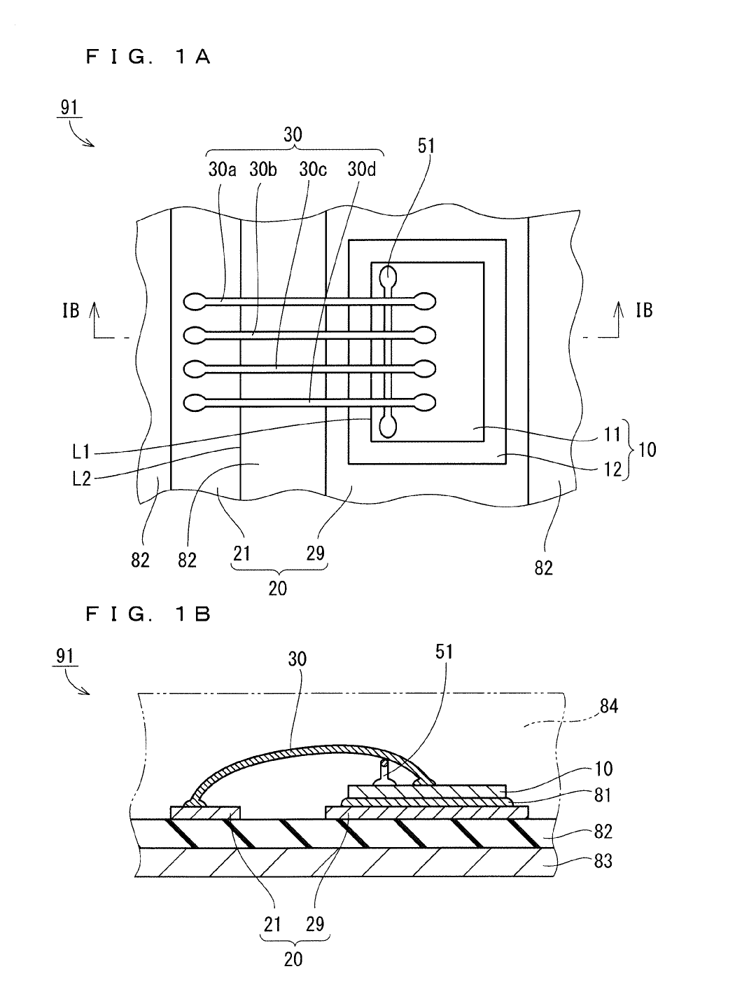

FIG. 1A is a partial plan view schematically showing a configuration of a power module 91 (power semiconductor device) according to this preferred embodiment. FIG. 1B is a schematic partial cross-sectional view taken along the line IB-IB in FIG. 1A. As to a sealing portion 84, only the surface thereof is shown to make the drawings clearer.

The power module 91 includes a power semiconductor element 10, a wiring pattern 20, a plurality of main bonding wires 30, a sub-bonding wire 51, a solder portion 81, an insulating substrate 82, a base layer 83, and the sealing portion 84.

The wiring pattern 20 is made of a conductor such as a metal and includes a wiring portion 21 (first wiring portion) and a mounting portion 29. The wiring portion 21 has an edge having a straight-line portion L2 (second straight-line portion).

The power semiconductor element 10 is mounted above the mounting portion 29 of the wiring pattern 20 by including the solder portion 81 therebetween. The wiring portion 21 is apart from the power semiconductor element 10.

The semiconductor element 10 includes, on a surface portion 12 thereof, an electrode pad 11 (electrode layer) made of a conductor such as a metal. The electrode pad 11 has an edge having a straight-line portion L1 (first straight-line portion). The straight-line portions L1 and L2 face each other. In this preferred embodiment, the straight-line portions L1 and L2 are parallel to each other.

The power semiconductor element 10 is typically a power device that is operable at 150° C. or above and is, for example, a metal insulator semiconductor field effect transistor (MISFET) such as a metal oxide semiconductor field effect transistor (MOSFET) or is an insulated gate bipolar transistor (IGBT) or a diode. The electrode pad 11 is not a signal current pad such as a gate pad but a main current pad. In the above example of the power semiconductor element, the electrode pad 11 is a source electrode pad, a drain electrode pad, an emitter electrode pad, a collector electrode pad, an anode electrode pad, or a cathode electrode pad. Typically, the electrode pad 11 is a source electrode pad, an emitter electrode pad, or an anode electrode pad.

The main bonding wires 30 include main wires 30a, 30b, 30c, and 30d. Each of the main wires 30a, 30b, 30c, and 30d has one end (the right end in FIG. 1A) on the electrode pad 11 and the other end (the left end in FIG. 1A) on the wiring portion 21.

The sub-bonding wire 51 has the both ends on the electrode pad 11. The sub-bonding wire 51 supports the main bonding wires 30. The sub-bonding wire 51 intersects with each of the main wires 30a, 30b, 30c, and 30d in a planar layout (FIG. 1A) and is orthogonal to each of the main wires 30a, 30b, 30c, and 30d in FIG. 1A. The sub-bonding wire 51 extends along at least one of the straight-line portions L1 and L2 in a planar layout. In this preferred embodiment, the sub-bonding wire 51 extends along each of the straight-line portions L1 and L2.

The material for the sealing portion 84 is an insulating material and may be a resin or a gel. If the sealing portion 84 is a gel, a case for housing the gel may be provided.

In this preferred embodiment, the main bonding wires 30 that electrically connect the electrode pad 11 of the power semiconductor element 10 and the wiring portion 21 are supported by the sub-bonding wire 51. This can enhance the mechanical stability of the electrical paths between the electrode pad 11 and the wiring portion 21. Therefore, the undesirable approach of the main bonding wires 30 as the electrical paths between the electrode pad 11 and the wiring portion 21 to the peripheral positions having different potentials can be prevented. For example, the main bonding wires 30 can be prevented from approaching the edge of the surface portion 12 of the power semiconductor element 10.

The electrical paths between the electrode pad 11 and the wiring portion 21 are formed not only by the main bonding wires 30 but also by the sub-bonding wire 51. Consequently, the electrical paths are dispersed. Thus, the concentration of current in the power module 91 can be relieved. Particularly, in a case where the sub-bonding wire 51 has the both ends on the electrode pad 11 as in this preferred embodiment, the electrical paths from the wiring portion 21 toward the electrode pad 11 branch at the points in which the main bonding wires 30 and the sub-bonding wire 51 are in contact with one another and extend not only toward the other ends of the main bonding wires 30 (the right ends in FIG. 1A) but also toward the both ends of the sub-bonding wire. That is, the points to which the electrical paths from the wiring portion 21 are connected are further dispersed on the electrode pad 11. Therefore, the local concentration of current in the electrode pad 11 of the power semiconductor element 10 can be relieved.

As described above, the concentration of current can be relieved by dispersing the electrical paths between the electrode pad 11 of the power semiconductor element 10 and the wiring portion 21 while the mechanical stability of the electrical paths is enhanced. This can lead to, for example, an improvement in the yields in the processes for manufacturing the power module 91. Moreover, the lifetime of the power module 91 can be extended. Furthermore, a decrease in current loss can lead to energy savings.

The power semiconductor element 10 is typically a power device that is operable at 150° C. or above, so that the relatively large thermal expansion and contraction are generated in the power module 91. The anisotropy of the thermal expansion and contraction is likely to be developed due to the presence of the main bonding wires 30. Particularly, when the main wires 30a, 30b, 30c, and 30d are disposed in parallel as shown in FIG. 1A, the anisotropy of the thermal expansion and contraction that is developed due to the presence of the main wires 30a, 30b, 30c, and 30d in the power module 91, in other words, due to the presence of the effects of the extending directions (the horizontal directions in FIG. 1A) of the respective main wires 30a, 30b, 30c, and 30d is more likely to cause problems. In this preferred embodiment, the anisotropy can be relieved by the presence of the sub-bonding wire 51 that extends in the directions different from those of the main wires 30a, 30b, 30c, and 30d. Thus, the stress in the power module 91 can be relieved.

The power semiconductor element 10 may be one of a silicon carbide semiconductor element and a gallium arsenide semiconductor element. Silicon carbide (SiC) and gallium arsenide (GaAs) have linear expansion coefficients larger than that of silicon (Si), which is most common as the semiconductor material. The typical values of the linear expansion coefficients are, for example, 4.5×10⁻⁶/K for SiC, 6.86×10⁻⁶/K for GaAs while the value is 2.4×10⁻⁶/K for Si. Therefore, if a silicon carbide semiconductor element or a gallium arsenide semiconductor element is included, the stress in the power module 91 particularly needs to be suppressed. Thus, the application of this preferred embodiment provides particularly significant advantages.

The main bonding wires 30 include not a single main wire but the main wires 30a, 30b, 30c, and 30d because the main bonding wires 30 are not the paths for a small current such as a signal current but the electrical paths for the main current to be controlled by the power semiconductor element 10. When a large current is handled as described above, the dispersion of the current paths by the sub-bonding wire 51 provides particularly significant advantages.

The sub-bonding wire 51 intersects with each of the main wires 30a, 30b, 30c, and 30d in a planar layout (FIG. 1A). Therefore, one sub-bonding wire 51 can support a plurality of main wires 30a, 30b, 30c, and 30d.

In many cases, the main bonding wires 30 are disposed to be substantially orthogonal to at least one of the straight-line portions L1 and L2 in a planar layout (FIG. 1A). Thus, in a case where the sub-bonding wire 51 extends along at least one of the straight-line portions L1 and L2 in a planar layout as in this preferred embodiment, the main bonding wires 30 and the sub-bonding wire 51 can be made substantially orthogonal. Consequently, the mechanical stability of the electrical paths between the electrode pad 11 of the power semiconductor element 10 and the wiring portion 21 can be further enhanced.

The sub-bonding wire 51 may have a stiffness lower than that of the main bonding wires 30. When this is the case, the bonding wire 51 is less likely to damage the main bonding wires 30 that are more important as the electrical paths.

The sub-bonding wire 51 may have a wire diameter different from the wire diameters of the main bonding wires 30. When this is the case, the extending state of the main bonding wires 30 that is required in the power module 91, more particularly, the curved state of the wire loops can be adjusted by the wire diameter of the sub-bonding wire 51.

The main bonding wires 30 and the sub-bonding wire 51 may be made of the same material and may have the same wire diameter. When this is the case, the processes for forming the main bonding wires 30 and the sub-bonding wire 51 are similar. Thus, the main bonding wires 30 and the sub-bonding wire 51 can be formed more easily.

Although the circuit board including the wiring pattern 20, the insulating substrate 82, and the base layer 83 is used in this preferred embodiment, an alternative configuration may be employed. For example, a lead frame may be included. When this is the case, a part of the lead frame corresponds to the first wiring portion. The straight-line portions L1 and L2 are not necessarily provided. Depending on the amount of current, one main bonding wire 30 may be included in place of the plurality of main bonding wires 30.

### Second Preferred Embodiment

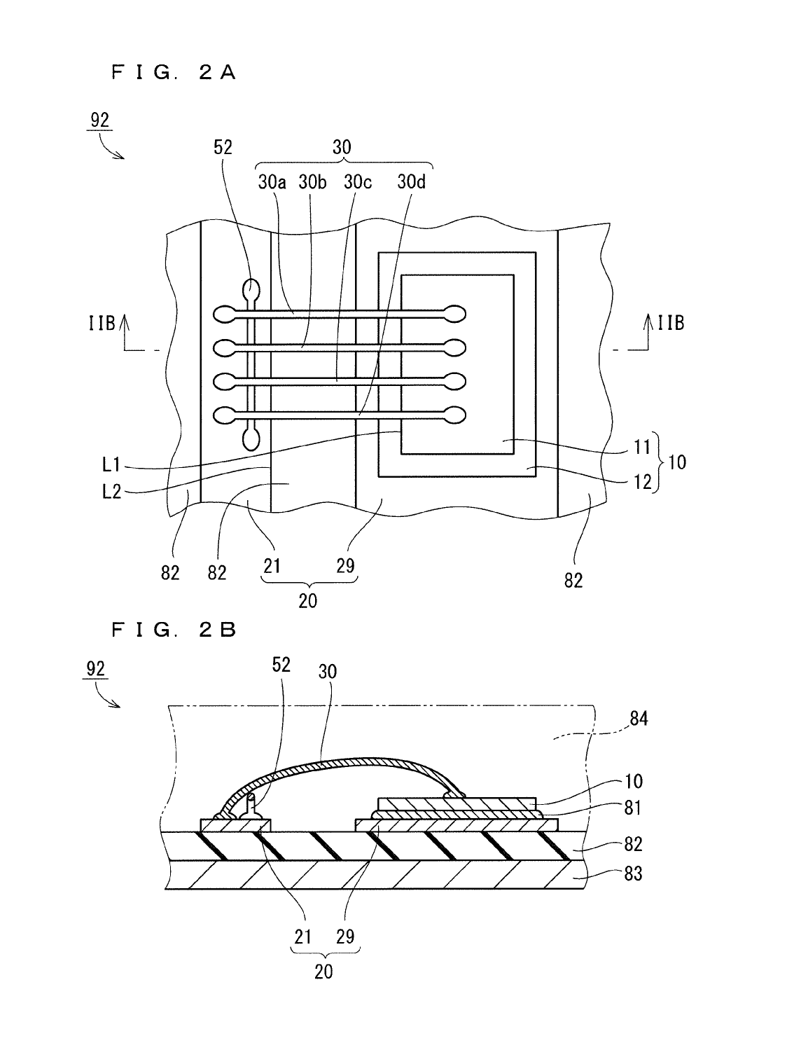

FIG. 2A is a partial pan view schematically showing a configuration of a power module 92 (power semiconductor device) according to this preferred embodiment. FIG. 2B is a schematic partial cross-sectional view taken along the line IIB-IIB in FIG. 2A. As to the sealing portion 84, only the surface thereof is shown to make the drawings clearer.

The power module 92 (power semiconductor device) includes at least one sub-bonding wire 52 in place of the sub-bonding wire 51 (FIGS. 1A and 1B) in the first preferred embodiment. The sub-bonding wire 52 has the both ends on the wiring portion 21. The sub-bonding wire 52 intersects with each of the main wires 30a, 30b, 30c, and 30d in a planar layout (FIG. 2A) and is orthogonal to each of the main wires 30a, 30b, 30c, and 30d in FIG. 2A. The sub-bonding wire 52 extends along at least one of the straight-line portions L1 and L2 in a planar layout. In this preferred embodiment, the sub-bonding wire 52 extends along each of the straight-line portions L1 and L2.

The configuration except for the above is substantially the same as the configuration of the first preferred embodiment described above. Therefore, the same or corresponding elements are given the same reference signs and the description thereof is not repeated.

In this preferred embodiment, similarly to the first preferred embodiment, the concentration of current can be relieved by dispersing the electrical paths between the electrode pad 11 of the power semiconductor element 10 and the wiring portion while the mechanical stability of the electrical paths is enhanced. The stress in the power module 92 can also be relived.

Particularly, in this preferred embodiment, the sub-bonding wire 52 has the both ends not on the electrode pad 11 but on the wiring portion 21. Therefore, the both ends of the sub-bonding wire 52 can be positioned irrespective of the size of the electrode pad 11. This is particularly advantageous when the electrode pad 11 is mall.

The sub-bonding wire 52 intersects with each of the main wires 30a, 30b, 30c, and 30d in a planar layout (FIG. 2A). This enables one sub-bonding wire 52 to support a plurality of main wires.

In a case where the sub-bonding wire 52 extends along at least one of the straight-line portions L1 and L2 in a planar layout as in this preferred embodiment, the main bonding wires 30 and the sub-bonding wire 52 can be made substantially orthogonal. Consequently, the mechanical stability of the electrical paths between the electrode pad 11 of the power semiconductor element 10 and the wiring portion 21 can be further enhanced.

As to the sub-bonding wire 52, the wiring diameter and the material that are similar to those in the first preferred embodiment are selected, whereby the similar effects can be obtained.

In addition to the configuration of this preferred embodiment, the sub-bonding wire 51 in the first preferred embodiment may be further provided.

### Third Preferred Embodiment

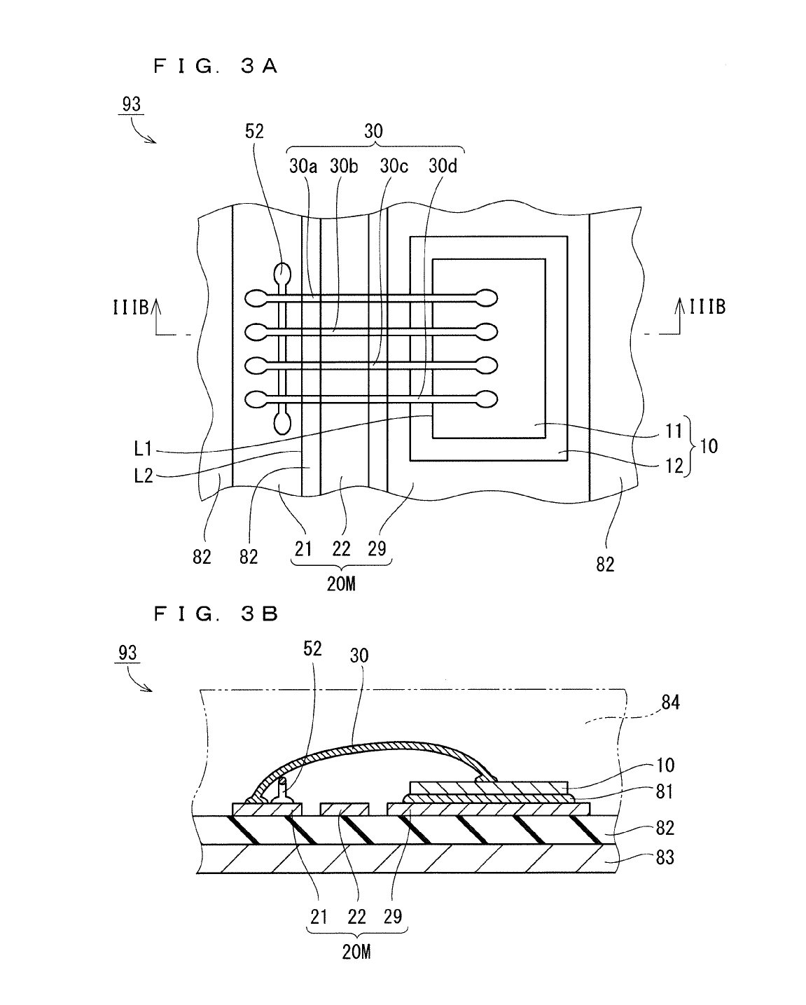

FIG. 3A is a partial plan view schematically showing a configuration of a power module 93 (power semiconductor device) according to this preferred embodiment. FIG. 3B is a schematic partial cross-sectional view taken along the line IIIB-IIIB in FIG. 3A. As to the sealing portion 84, only the surface thereof is shown to make the drawings clearer.

The power module 93 (power semiconductor device) has a wiring pattern 20M in place of the wiring pattern 20. The wiring pattern 20M includes a wiring portion 22 (second wiring portion) in addition to the configuration of the wiring pattern 20. The wiring portion 22 is disposed between the wiring portion 21 and the mounting portion 29. In other words, the wiring portion 22 is disposed between the wiring portion 21 and the electrode pad 11 because the electrode pad 11 is located on the mounting portion 29. The wiring portion 22 is apart from the main bonding wires 30 and is bridged over by the main bonding wires 30.

The configuration except for the above is substantially the same as the configuration of the second preferred embodiment described above. Therefore, the same or corresponding elements are given the same reference signs and the description thereof is not repeated.

In this preferred embodiment, similarly to the second preferred embodiment, the concentration of current can be relieved by dispersing the electrical paths between the electrode pad 11 of the power semiconductor element 10 and the wiring portion 21 while the mechanical stability of the electrical paths is enhanced. The stress in the power module 93 can also be relived.

Particularly, in this preferred embodiment, the undesirable approach of the main bonding wires 30 as the electrical paths between the power semiconductor element 10 and the wiring portion 21 to the wiring portion 22 can be prevented.

### Fourth Preferred Embodiment

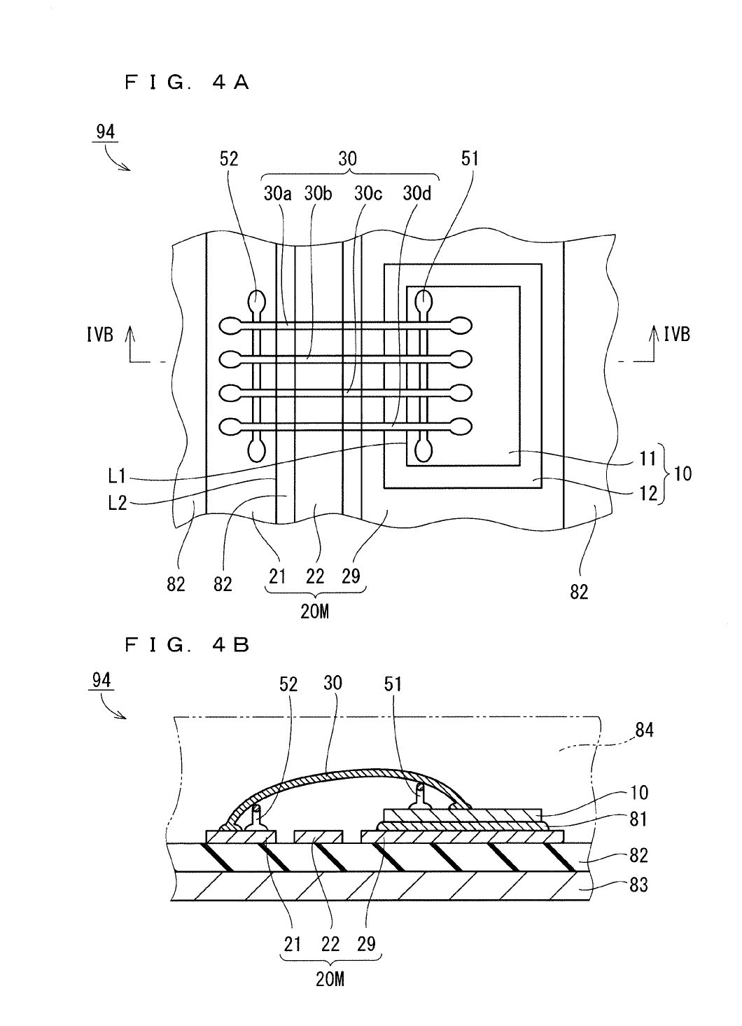

FIG. 4A is a partial plan view schematically showing a configuration of a power module 94 (power semiconductor device) according to this preferred embodiment. FIG. 4B is a schematic partial cross-sectional view taken along the line IVB-IVB in FIG. 4A. As to the sealing portion 84, only the surface thereof is shown to make the drawings clearer.

The power module 94 (power semiconductor device) includes the sub-bonding wire 51 that is similar to the one in the first preferred embodiment. The configuration except for the above is substantially the same as the configuration of the third preferred embodiment described above. Therefore, the same or corresponding elements are given the same reference signs and the description thereof is not repeated.

In this preferred embodiment, the sub-bonding wire 51 is provided, whereby the effects described in the third preferred embodiment can be more reliably obtained. The sub-bonding wire 52 may be omitted if it is not necessary.

### Fifth Preferred Embodiment

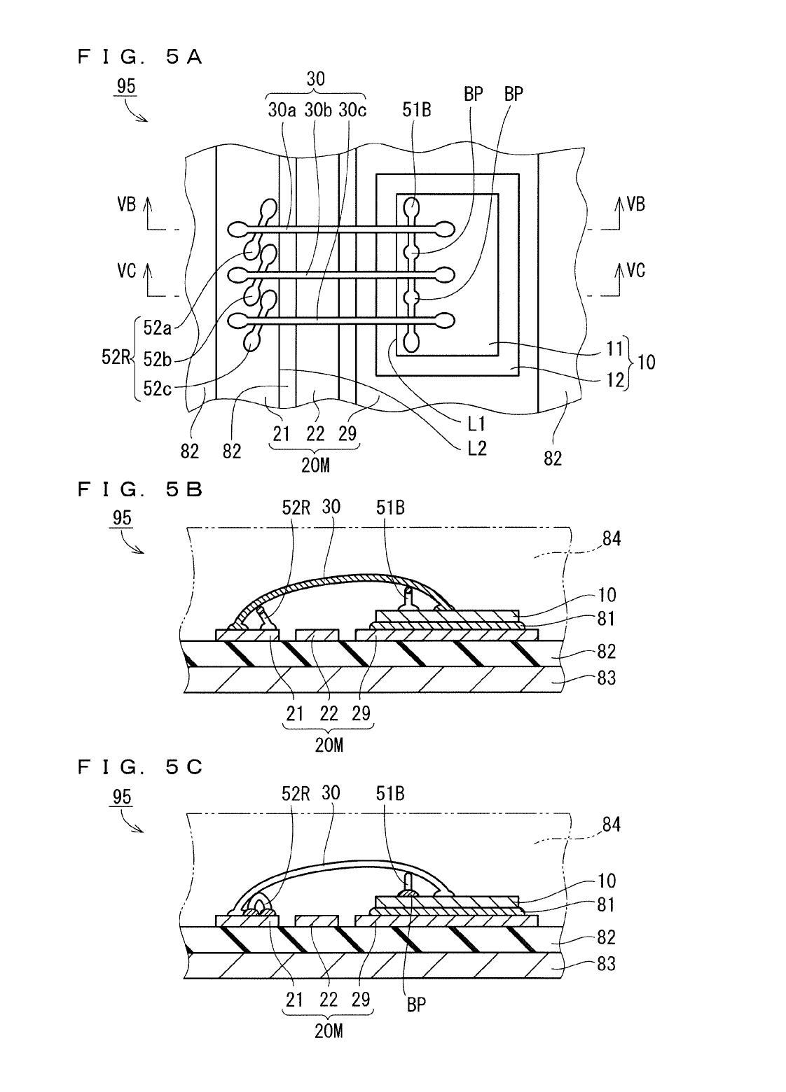

FIG. 5A is a partial pan view schematically showing a configuration of a power module 95 (power semiconductor device) according to this preferred embodiment. FIG. 5B is a schematic partial cross-sectional view taken along the line VB-VB in FIG. 5A. FIG. 5C is a schematic partial cross-sectional view taken along the line VC-VC in FIG. 5A. As to the sealing portion 84, only the surface thereof is shown to make the drawings clearer.

The power module 95 (power semiconductor device) includes at least one sub-bonding wire 52R in place of the sub-bonding wire 52 (FIGS. 4A and 4B). In this preferred embodiment, the sub-bonding wires 52R include sub-wires 52a, 52b, and 52c. The sub-wire 52a supports only the main wire 30a out of the main wires 30a, 30b, and 30c. The sub-wire 52b supports only the main wire 30b out of the main wires 30a, 30b, and 30c.

The power module 95 includes at least one sub-bonding wire 51B in place of the sub-bonding wire 51 (FIGS. 4A and 4B). The sub-bonding wire 51B has bonding points BP not only at the both ends but also between the main wire 30a and the main wire 30b and between the main wire 30b and the main wire 30c in a planar layout. The sub-bonding wire 51B extends along at least one of the straight-line portions L1 and L2 in a planar layout. In this preferred embodiment, the sub-bonding wire 51B extends along each of the straight-line portions L1 and L2.

The configuration except for the above is substantially the same as the configuration of the fourth preferred embodiment described above. Therefore, the same or corresponding elements are given the same reference signs and the description thereof is not repeated.

In this preferred embodiment, each of the sub-wires 52a, 52b, and 52c that are included in the sub-bonding wires 52R can be shortened compared with the sub-bonding wire 52 (FIGS. 4A and 4B). This can improve the stiffness of the sub-wires 52a, 52b, and 52c. Thus, the mechanical stability of the electrical paths between the electrode pad 11 of the power semiconductor element 10 and the wiring portion 21 can be further enhanced.

The sub-bonding wire 51B has the bonding points BP at positions other than the both ends thereof, thereby having a higher stiffness. Thus, the mechanical stability of the electrical paths between the electrode pad 11 of the power semiconductor element 10 and the wiring portion 21 can be further enhanced.

As compared to the sub-bonding wires 52R, the sub-bonding wire 51B can be easily extended along at least one of the straight-line portions L1 and L2. Thus, the bonding wires 30 and the sub-bonding wire 51B can be easily made substantially orthogonal. Consequently, the mechanical stability of the electrical paths between the electrode pad 11 of the power semiconductor element 10 and the wiring portion 21 can be further enhanced.

As to the sub-bonding wires 51B and 52R, the wiring diameters and the materials that are similar to those in the first preferred embodiment are selected, whereby the similar effects can be obtained.

The wires having, similarly to the sub-bonding wire 51B, the bonding points BP at positions other than the both ends thereof may be disposed on the wiring portion 21. The sub-bonding wires 52R such as the sub-wires 52a, 52b, and 52c may be disposed on the electrode pad 11.

In the present invention, the above preferred embodiments can be arbitrarily combined, or each preferred embodiment can be appropriately varied or omitted within the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A power semiconductor device comprising:
a power semiconductor element including an electrode layer made of a conductor;
a first wiring portion that is apart from said power semiconductor element, said first wiring portion being made of a conductor;
at least one main bonding wire having one end on said electrode layer and the other end on said first wiring portion; and
at least one sub-bonding wire that supports said main bonding wire, said sub-bonding wire having both ends on one of said electrode layer and said first wiring portion.

2. The power semiconductor device according to claim 1, wherein said at least one main bonding wire includes first and second main wires.

3. The power semiconductor device according to claim 2, wherein said at least one sub-bonding wire intersects with said first and second main wires in a planar layout.

4. The power semiconductor device according to claim 2, wherein said at least one sub-bonding wire includes a first sub-wire that supports only one of said first and second main wires and a second sub-wire that supports the other main wire.

5. The power semiconductor device according to claim 2, wherein said at least one sub-bonding wire includes a bonding wire having a bonding point between said first and second main wires in a planar layout.

6. The power semiconductor device according to claim 1, wherein
said electrode layer of said power semiconductor element has an edge having a first straight-line portion,
said first wiring portion has an edge having a second straight-line portion that faces said first straight-line portion, and
said sub-bonding wire extends along at least one of said first straight-line portion and said second straight-line portion in a planar layout.

7. The power semiconductor device according claim 1, further comprising a second wiring portion located between said electrode layer of said power semiconductor element and said first wiring portion, said second wiring portion being bridged over by said main bonding wire.

8. The power semiconductor device according to claim 1, wherein said sub-bonding wire has a stiffness lower than that of said main bonding wire.

9. The power semiconductor device according to claim 1, wherein said sub-bonding wire has a wire diameter different from that of said main bonding wire.

10. The power semiconductor device according to claim 1, wherein said main bonding wire and said sub-bonding wire are made of an identical material and have an identical wire diameter.

11. The power semiconductor device according to claim 1, wherein said power semiconductor element is one of a silicon carbide semiconductor element and a gallium arsenide semiconductor element.
